(19) United States
(12) Patent Application Publication
(10) Pub. No.: US 2010/0112194 A1
(43) Pub. Date: May 6, 2010

(54) MASK FIXING DEVICE IN VACUUM PROCESSING APPARATUS

(75) Inventors: Masato Inoue, Chigasaki-shi (JP); Shin Matsui, Fujisawa-shi (JP); Toshiaki Himeji, Kamakura-shi (JP)

Correspondence Address: FITZPATRICK CELLA HARPER & SCINTO, 1290 Avenue of the Americas, NEW YORK, NY, 10104-3800, US

(73) Assignee: CANON ANELVA CORPORATION, Kawasaki-shi (JP)

(21) Appl. No.: 12/624,990

(22) Filed: Nov. 24, 2009

Related U.S. Application Data
(63) Continuation of application No. PCT/JP2008/056061, filed on Mar. 28, 2008.

(51) Int. Cl. B05D 5/06; C23C 14/24; C23C 14/34

(52) U.S. Cl. 427/66; 204/298.11; 118/721; 204/192.26

(57) ABSTRACT

A vacuum processing apparatus which processes an object to be processed with the use of a mask membrane plane of magnetic material and a mask frame of the magnetic material is characterized in that the mask of the magnetic material is attracted by an electro-permanent magnet that is disposed in an opposite side of the mask with respect to the surface having the object to be processed mounted thereon.

### CROSS-REFERENCES TO RELATED APPLICATIONS

This application is a continuation application of International Application No. PCT/JP2008/056061, filed on Mar. 28, 2008, the entire contents of which are incorporated by reference herein.

### TECHNICAL FIELD

The present invention relates to a vacuum processing apparatus, a method for manufacturing an image display apparatus using the vacuum processing apparatus, and an electronic device manufactured by the vacuum processing apparatus.

### BACKGROUND ART

In a glass-substrate processing apparatus for a flat panel display represented by an organic electroluminescence device, a desired function is generally given to a substrate by forming a desired pattern of desired accuracy on the substrate. As a pattern-forming method, there are a vacuum vapor-deposition method, a sputtering method, a photolithographic method, a screen printing method and the like. However, an accuracy of higher definition in pattern-forming is required to a pattern forming apparatus, as a display capability of higher definition is required to the display.

As is described in Patent Document 1, the vacuum vapor-deposition method as well as a sputtering method is known as a technique which can realize a higher pattern accuracy at a lower price and with higher reliability than other techniques. In a manufacture of the display which uses an organic electroluminescence device as a display device in particular, the vacuum vapor-deposition method has received attention as a dry process that gives extremely little moisture damage to the device, which is given in a wet process used in the photolithographic method.

When taking a method of forming a patterned film with the vacuum vapor-deposition method as an example, the method forms a desired pattern on a substrate which is an object to be film-formed, by vapor-depositing the material on the substrate over a mask having an aperture previously formed on a patterning portion, in a state of making the mask closely brought into contact with the substrate. Accordingly, a finish accuracy of the pattern directly depends on a finish accuracy of the mask, so that it is required to develop means of forming a fine pattern of high accuracy on the mask (Patent Document 2, for instance).

The thickness of the mask needs to be lowered so as to form the fine pattern on the mask, and at the same time, the mask is required not to cause flexure or a wrinkle in order to secure its close contactability with the object to be film-formed and the pattern accuracy of the mask. For that purpose, there is a method described in Patent Document 3, which fixes a mask made from metal having a thickness of 500 μm or less to a frame while applying tension to the mask.

The metallic mask has a structure of being weld-bonded with a frame at the periphery while the tension is applied to the mask, the tension always works in the inside of the mask, and at the same time, the reaction force always works on the frame. Thereby, the flatness of the mask is secured, but on the other hand, the frame is required to have high rigidity. The reason is because the mask has to stand against the reaction force against the tension working toward in an inward direction, and if the rigidity of the frame was weak, the frame itself is deformed by the reaction force, the tension is relaxed, and as a result, a predetermined accuracy cannot be retained.

From the above reason, a high rigidity is required to the mask frame in order to form a fine pattern of high accuracy, which means that the weight of the mask made from metal increases. As multi-pattern formation is required and the size of the object to be film-formed itself becomes large according to a request for enhanced processing capability, the weight of the mask further increases. The mask made from metal for a size of 55 inches (approximately 1,300×800 mm), for instance, occasionally has a weight of reaching 300 kg.

The increase of the size of the mask and the resultant increase of the weight lead to the increase of a scale of an alignment mechanism for the object to be film-formed and the mask, and a mechanism for moving the mask, in the film-forming apparatus, which causes difficulty in maintaining the high accuracy. Accordingly, means for simply handling even a mask with a heavy weight while maintaining the high accuracy is required to solve a problem which is concerned to the film-forming apparatus using the mask.

Furthermore, in addition to this, it becomes generally necessary in the film-forming step of the vacuum vapor-deposition method for the surface to be pattern-formed of the object to be film-formed to take an attitude of being directed downward and opposing to an evaporation source, which is referred to as a face-down (depo-up) method. On the other hand, an alignment step is generally conducted by slightly moving both or any one of the mask and the object to be film-formed in a state of having mounted the mask and the object to be film-formed on a table which has a fixed accuracy of flatness. When considering the steps from the alignment step to the film-forming step, means is necessary which holds/maintains the mask and the object to be film-formed that have been aligned once, without causing a misalignment even in an upside-down state.

From the above reason, in order to secure the high pattern accuracy while coping with a large-sized object to be film-formed, the mask fixing mechanism is required to realize two functions of holding/fixing a heavy-weighted mask without causing misalignment and securing the close contactability of the mask with the object to be film-formed.

There is means in a conventional technology for realizing the above requirement, which reduces the weight of the mask while securing an alignment of high accuracy by employing a mask for a region that has been divided into small sizes and the vapor-deposition method in multi-pattern formation apparatus, as is described in Patent Document 4.

FIG. 5 illustrates an example of a schematic structure in a conventional technology (Patent Document 4). The structure has a mask having a plurality of same pattern formed masks on the single substrate base 52 and a mask alignment mechanism 51 for aligning the mask with a substrate in an alignment section 50; and reversing the substrate into an attitude of face-down in a substrate-reversing section 53 after having finished each alignment, and conducting vapor deposition in a vacuum chamber 55. A vapor-deposition process is conducted by using a film-forming source 56 in a film-forming section 54 in the vacuum chamber 55. In addition, a magnet for fixing a metallic mask of magnetic material has been used as means for fixing the mask and the object to be film-formed, but there has been such a danger that a misalignment due to a scratch or an impact originating from the contact of the mask with the object to be film-formed might have occurred because a necessary attraction power has increased due to the increased weight of the mask.

Among conventional technologies for solving the above problem, an invention according to Patent Document 5 discloses a technology of holding an object to be film-formed with an electrostatic chuck, and forming a mask from silicon material of superiority in flatness. Referring to FIG. 6, it is understood that a glass substrate 64 which is the object to be film-formed is held by a stage 65 due to an electrostatic attraction power, and the mask is held by an additional holder 63. For this reason, there is no misalignment due to the scratch and the impact, which may occur when the object is fixed by the above described magnet.

According to an embodiment described in FIG. 6, a vapor-deposition mask 62 which is held by the glass substrate 64 and the holder 63 is structured to have a face-down attitude of being directed downward and opposing to a crucible 61 which is a vapor-deposition source, and is arranged in the inside of a vacuum chamber 60. In this conventional technology, means for fixing the glass substrate 64 is structured so as to apply voltage to an electrode 65A built in the stage 65, and make the electrode 65A function as an electrostatic chuck. Cameras 66A and 66B are provided so as to align the vapor-deposition mask 62 with the glass substrate 64.

The mask membrane plane has a fine flexure even though a tension is applied to the plane, and has a difference between the flatnesses of itself and the substrate of the object to be film-formed. Because of this, a wrinkle or the like is formed when the mask is brought into contact with the object to be film-formed. As a result, when a gap is formed between the contact planes of the mask and the object to be film-formed, the vapor-deposition material results in entering even a place other than an aperture of the mask, which accordingly incurs an aggravation of the accuracy of a finished pattern. In order to prevent the aggravation of the patterning accuracy, which is referred to as “film-formation blur”, it is required to enhance the close contactability of the mask to the object to be film-formed as highly as possible.

As a conventional technology for realizing the above requirement, there is a method for increasing the closely contacting area by fixing the mask to the object to be film-formed sequentially from one opposing end, as is described in Patent Document 6. FIG. 7 illustrates a sectional view of steps for arranging a magnet (permanent magnet) in a vapor-deposition process of the conventional technology. FIG. 7 illustrates a procedure of bringing a metal mask 72 into close contact with a substrate 71 while using a tabular magnet (permanent magnet) 73 for securing the close contact between both, in a state of arranging the metal mask 72 and the substrate 71 in parallel. The procedure enhances the close contactability of the metal mask 72 to the substrate 71 by bringing the tabular magnet (permanent magnet) in contact with the substrate 71 sequentially from one end 72a.

By the way, an electro-permanent magnet is known (Patent Document 7) for fixing an article to be worked when a heavy article such as a metal mold is mechanically worked. The electro-permanent magnet is a magnetic device including the permanent magnet and a coil, and can adjust the magnetic attraction of itself to the contact portion by applying an electric current to the coil for such a short period of time as approximately 0.5 seconds. The electro-permanent magnet is different from an electromagnet which needs to always pass an electric current during attraction. It need to pass the electric current only for a short period of time during attraction and non-attraction, and accordingly has features of causing little problem of heat generation and being superior in energy-saving properties.

Patent Document 1: Japanese Patent Publication No. H06-51905
Patent Document 2: Japanese Patent Application Laid-Open No. H10-41069

### Patent Document 3: Japanese Patent No. 3539125

### Patent Document 4: Japanese Patent Application Laid-Open No. 2003-73804

### Patent Document 5: Japanese Patent Application Laid-Open No. 2004-183044

### Patent Document 6: Japanese Patent Application Laid-Open No. 2004-152704

Patent Document 7: Japanese Patent Publication No. H02-39849

### SUMMARY OF THE INVENTION

However, the above described solution with the use of a divided mask and divided vapor-deposition in the conventional technology described in the Patent Document 4 has a problem that the apparatus increases the tact time and cannot cope with a large-sized substrate in which patterns are collectively vapor-deposited for multi-panel formation in a substrate.

The means for fixing the object to be film-formed with an electrostatic chuck, which is the above described conventional technology described in the Patent Document 5, has the following problems. The object to be film-formed is generally made from glass, which is an insulator, has a high volume resistivity and does not show the electrostatic attraction force at normal temperature. Because of this, in order to decrease the volume resistivity, the film-forming apparatus needs procedures of the raising and falling temperature and an additional mechanism. Alternatively, when a single electrode type of an electrostatic chuck is used, the film-forming apparatus needs a new step of applying an electroconductive film on the glass and imparting properties capable of being electrostatically attracted to the glass. As a result of having needed an additional countermeasure as was described above, the film-forming apparatus has caused a new problem of incurring the increase of a product cost, and the increase of the tact time of the apparatus and an apparatus cost.

In addition, the above described procedure of enhancing the close contactability of the mask to the object to be film-formed, which is described in the Patent Document 6, has a problem of limiting a degree of freedom when a size of the object to be film-formed has been changed because the procedure sequentially fixes from the one side at any time. The procedure has caused a problem that the degree of freedom and extendibility in designing the apparatus are limited particularly when the apparatus needs to cope with the large-sized substrate of an object to be film-formed.

In addition, a large number of documents on a type of using a permanent magnet are disclosed as means of closely contacting and fixing the mask onto the substrate in the vacuum, while including the above described Patent Documents 4 to 6. However, when structuring the fixing mechanism with the use of the permanent magnet, it is necessary for controlling an attracting operation and a detaching operation to adjust the attraction force by moving the permanent magnet and changing the distance between the object to be attracted and the permanent magnet. When the operation is conducted while a film is formed in a vacuum, a handling method of the permanent magnets, responding to the movement of the object becomes complicated, a power necessary for a driving system increases because of a large-sized apparatus, and results in increasing an facility power of the apparatus, which causes a problem that energy-saving properties and extendibility are impaired. In addition, the type of apparatus needs a space for moving the permanent magnet for control, in the periphery of the base, and accordingly causes a problem that the rigidity of the stage decreases if the space-saving properties were pursued.

One aspect of the present invention is a vacuum processing apparatus characterized in that the apparatus comprises: vacuum exhausting means; a chamber which can exhaust air in the inner part with the vacuum exhausting means;

a base for mounting an object to be processed thereon; a mask of magnetic material disposed at one surface side of the object; and an electro-permanent magnet included in the base, which is disposed at the other surface side of the object, wherein the object is fixed to the base by attracting the mask of the magnetic material with the electro-permanent magnet.

One exemplary embodiment of the vacuum processing apparatus according to the present invention is characterized in that the component of the electro-permanent magnet has a degassing rate from the material in an amount of 4.0×10⁻⁴ Pam/s or less per unit area.

One exemplary embodiment of the vacuum processing apparatus according to the present invention is characterized in that the surface of the component of the electro-permanent magnet has been subjected to plating treatment, blast treatment, polishing treatment, resin coating treatment, ceramic coating treatment or vacuum baking treatment, or is covered with a metal plate, a resin plate or a ceramic plate which have been subjected to any one of the treatments, so as to realize the desirable degassing rate.

One exemplary embodiment of the vacuum processing apparatus according to the present invention is characterized in that the contact plane of the electro-permanent magnet with respect to the object to be processed is provided with irregularities of an embossed shape or a fine pin shape, and the contact area with respect to the object to be processed is set at 98% or less.

One exemplary embodiment of the vacuum processing apparatus according to the present invention is characterized in that a mechanism is provided therein which can introduce a gas into and exhaust the gas from a fine space that is formed by the electro-permanent magnet and the object to be processed, and a mechanism for controlling the pressure of the gas is also provided.

One exemplary embodiment of the vacuum processing apparatus according to the present invention is characterized in that a thin plate is inserted to a space between the electro-permanent magnet and the object to be processed, and the object to be processed is fixed through the thin plate.

One exemplary embodiment of the vacuum processing apparatus according to the present invention is characterized in that the thin plate has been subjected to plating treatment, blast treatment, polishing treatment or vacuum baking treatment.

One exemplary embodiment of the vacuum processing apparatus according to the present invention is characterized in that the mask of magnetic material is structured by a mask membrane plane and a mask frame for fixing the periphery of the mask membrane plane, the mask membrane plane of the magnetic material is fixed by first magnet fixing unit formed from the electro-permanent magnet, and the mask frame of magnetic material is fixed by second magnet fixing unit formed from the electro-permanent magnet which works independently from the first magnet fixing unit.

One exemplary embodiment of the vacuum processing apparatus according to the present invention is characterized in that the first magnet fixing unit drives the electro-permanent magnet independently in the central part and the peripheral portion.

The mask membrane plane is deformed into a certain form due to its weight though being stretched by tension, and this deformation cannot be controlled because of including a complex error element such as working accuracy and flatness. Accordingly, when the contact has arbitrarily started from a small region or a site, the mask does not necessarily come in close contact with the object to be processed while following the deformation of the object. One exemplary embodiment of the vacuum processing apparatus according to the present invention is characterized in that the first magnet fixing unit for the mask membrane plane exerts a magnetic force on the mask membrane plane of the magnetic material so that a fixing operation of the mask starts from the central part of the object to be processed and ends in the peripheral portion thereof.

One exemplary embodiment of the vacuum processing apparatus according to the present invention is characterized in that the electro-permanent magnet is a demagnetizable type.

One exemplary embodiment of the vacuum processing apparatus according to the present invention is characterized in that the electro-permanent magnet controls the magnetic attraction force off only when having passed an electric current there through.

Another aspect of the present invention is a method for manufacturing an image display apparatus, characterized in that an electroconductive portion of the image display apparatus is formed with the use of the vacuum processing apparatus which is one aspect of the present invention.

Another aspect of the present invention is a method for manufacturing an image display apparatus, characterized in that a getter portion of the image display apparatus is formed with the use of the vacuum processing apparatus which is one aspect of the present invention.

Another aspect of the present invention is an electronic apparatus characterized in that the electronic apparatus has a pattern portion formed with the use of the vacuum processing apparatus which is one aspect of the present invention.

One exemplary embodiment of the vacuum processing apparatus according to the present invention is characterized in that the flatness of the contact plane of the electro-permanent magnet with respect to the object to be processed is set at 50 μm or less.

The present invention can provide an apparatus which can collectively form a pattern film having high accuracy on a mask even having problems that the weight increases for coping with a request of enlarging the size of an object to be processed and thereby the accuracy is aggravated, and at the same time, achieves a low cost and high productivity without using a component such as an electrostatic chuck. In addition, the present invention can realize an attracting state and a non-attracting state in a short period of time without driving a permanent magnet by using an external driving mechanism, and accordingly can provide an apparatus having energy-saving properties and high productivity. Furthermore, the apparatus does not need a space necessary for driving the permanent magnet with respect to the base, accordingly can provide a fixing mechanism therein having features of high rigidity and space-saving properties, and consequently can provide an apparatus which can easily cope with a request of further enlarging the size of the object to be processed and has high extendibility.

### BRIEF DESCRIPTION OF THE DRAWINGS

FIG. 1A is a sectional (elevational) view illustrating a schematic structure of a mask attraction mechanism according to the present invention;

FIG. 1B is a plan view of a mask to be used in the present invention;

FIG. 1C is a (elevational) view for describing a state of a magnetic field at the time when a mask of magnetic material is attracted by an electro-permanent magnet to be used in the present invention;

FIG. 1D is a sectional (elevational) view for describing a state of a magnetic field at the time when a mask of magnetic material is not attracted by an electro-permanent magnet to be used in the present invention;

FIG. 1E is a sectional (elevational) view illustrating one example of an exemplary embodiment of an electro-permanent magnet to be used in the present invention;

FIG. 1F is a sectional (elevational) view illustrating one example of an exemplary embodiment of an electro-permanent magnet to be used in the present invention;

FIG. 1G is a sectional (elevational) view illustrating one example of an exemplary embodiment of an electro-permanent magnet to be used in the present invention;

FIG. 2A is a view illustrating a state of a mask attraction mechanism according to the present invention at the time when alignment has been finished;

FIG. 2B is a view illustrating a state in which the mask attraction mechanism according to the present invention has finished the alignment and only a mask frame is attracted and fixed by the electro-permanent magnet;

FIG. 2C is a view illustrating a state in which the mask frame has been fixed and the central part of an object to be processed is brought into contact with the central part of a mask membrane plane, in the mask attraction mechanism according to the present invention;

FIG. 2D is a view illustrating a state in which the mask membrane plane is completely brought into contact with the object to be processed in the mask attraction mechanism according to the present invention;

FIG. 3 is a view illustrating a whole schematic structure of a vacuum processing apparatus according to the present invention;

FIGS. 4A and 4B are views illustrating one example of an image display apparatus manufactured by using a vacuum processing apparatus according to an exemplary embodiment according to the present invention;

FIG. 5 is a perspective view illustrating a schematic exemplary embodiment in a conventional technology;

FIG. 6 is a schematic view of an exemplary embodiment of a mask vapor-deposition apparatus in a conventional technology; and

FIG. 7 is a view illustrating steps of closely contacting and fixing a mask with a magnet, in a vapor-deposition process of a conventional technology.

### DESCRIPTION OF SYMBOLS

101 fixing mechanism for mask frame (electro-permanent magnet)
102 fixing mechanism for mask membrane plane (electro-permanent magnet)
102X fixing mechanism for central part of mask membrane plane (electro-permanent magnet)
102Y fixing mechanism for peripheral portion of mask membrane plane (electro-permanent magnet)
102a component of electro-permanent magnet which is magnetic material
102b polarization fixed magnet
102c polarization variable magnet
102d coil
102e magnet-fixing component
102f space for wires
102g non-magnetic material
102h embossed projection part
102i communication void space
102j through-hole
151a driving power source
151b driving power source
151c driving power source
152a wire
152b wire
152c wire
161 exhaust pipe
162 valve
163 vacuum pump
164 vacuum gauge
171 gas introduction pipe
172 valve
173 gas bomb
174 pressure gauge
200 mask
200a mask frame
200b mask membrane plane
300 object to be processed base
401a valve
401b valve
401c valve
402a vacuum pump
402b vacuum pump
403c vacuum pump

### DETAILED DESCRIPTION OF EMBODIMENTS

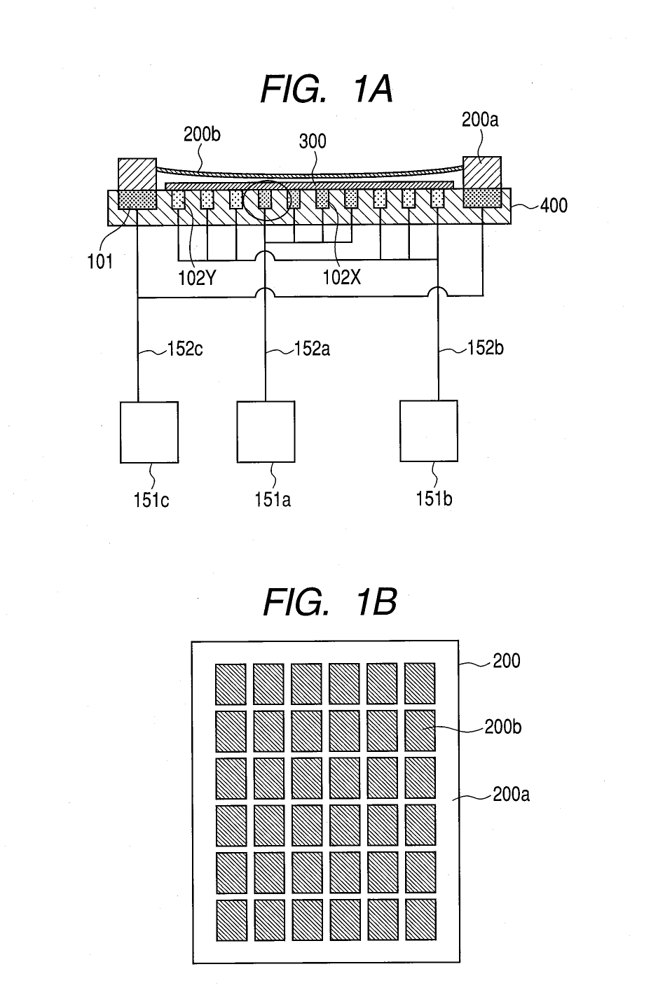

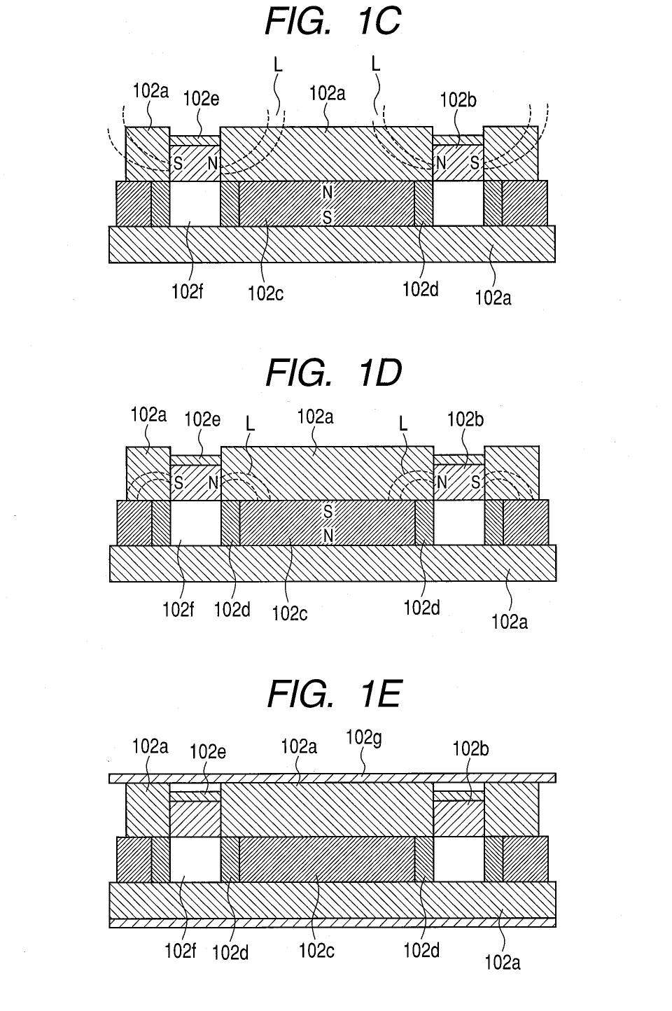

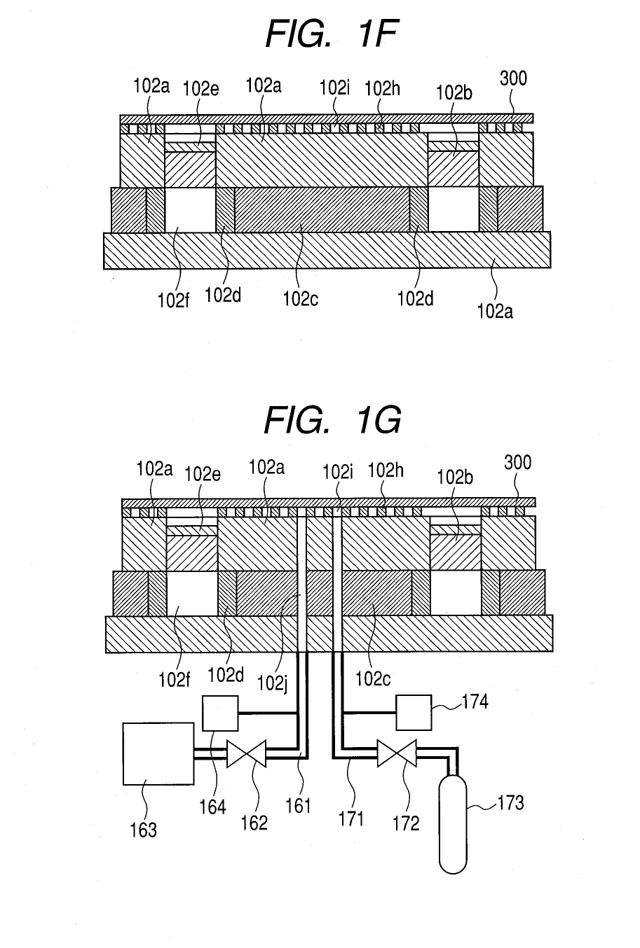

Exemplary embodiments according to the present invention will now be described below. FIG. 1A is a sectional (elevational) view illustrating a schematic structure of a base part of a vacuum processing apparatus according to a principle of the present invention. FIG. 1A illustrates a state of the vacuum processing apparatus at the time when the alignment of a mask 200 (including 200a and 200b) which will be described later with an object to be processed 300 has been finished, and the vapor-deposition is conducted in an upside-down state. The object to be processed 300 is arranged on an electro-permanent magnet 102 (including 102X and 102Y) which is arranged on a base 400, and the mask 200 is arranged thereon. The mask membrane plane 200b of the mask 200 is arranged in the upper part of the object to be processed 300 which is arranged on the electro-permanent magnet 102, and its periphery is surrounded by the mask frame 200a.

The mask 200 is structured by the mask frame 200a having high rigidity and the thin mask membrane plane 200b. The mask 200 is formed from magnetic material of metal, and in the present embodiment, magnetic material such as iron-based magnetic material is used. In order to reduce thermal expansion due to radiation-heat input, particularly during a vapor-deposition period, low thermal expansion material such as invar material is used. The mask membrane plane 200b which is formed from the magnetic material has fine apertures with a desired pattern formed thereon by an etching technique or the like. With the tendency of forming a pattern of high definition, it is required to reduce the thickness, and a metal film having a thickness of 50 microns or less can be formed.

FIG. 1B is a plan view of the mask 200. The mask 200 has the mask membrane plane 200b which has fine apertures provided thereon for forming a thin film pattern on a surface to be processed of the object to be processed 300, and has the mask frame 200a. If the mask membrane plane 200b which is a pattern region was thick, such a problem occurs that the film formed in the peripheral portion of the fine apertures becomes thin, so that the mask membrane plane 200b is thinner than the mask frame 200a, and for instance, is occasionally set at the thickness of 0.05 mm or less. When the mask membrane plane 200b becomes thin, film-forming particles which enter into a fine aperture from a diagonal direction can reach a substrate. The mask membrane plane 200b is fixed by a method of being welded with the mask frame 200a in the periphery in a state in which a tension has been beforehand applied, and is arranged so as to be surrounded by the mask frame 200a. The mask frame 200a of magnetic material is required to have rigidity necessary for controlling the deformation occurring due to a reaction force against the tension applied to the mask membrane plane 200b, to a specified value or lower. As a result, the whole weight of the mask 200 increases and a mask for a substrate size of approximately 1,300 mm×800 mm reaches a weight of 300 kg.

In FIG. 1A, an electro-permanent magnet 101 is arranged in an opposite side of the mask 200 with respect to the mounted surface of the object to be processed 300 on the electro-permanent magnet 102 so as to oppose to the mask frame 200a, in order that the electro-permanent magnet 101 attracts and fixes the mask frame 200a of the mask 200. The electro-permanent magnet 102 which includes the electro-permanent magnet 102X in the central part and the electro-permanent magnet 102Y in the peripheral portion is arranged in a portion sandwiched by the electro-permanent magnets 101 for the mask frame 200a. The electro-permanent magnet 102 is arranged in the opposite side of the mask 200 with respect to the mounted surface of the object to be processed 300 on the electro-permanent magnet 102, and achieves a function of attracting and fixing the mask membrane plane 200b of the mask 200. The electro-permanent magnet 102 is arranged so as to uniformly exert an attraction force on the mask membrane plane 200b. In order to make the electro-permanent magnets 101 and 102 generate a magnetic attraction force so as to attract and fix the mask 200, a driving power source 151c for the electro-permanent magnet 101, a driving power source 151a for the electro-permanent magnet 102X in the central part and a driving power source 151b for the electro-permanent magnet 102Y in the peripheral portion may apply a predetermined current to the electro-permanent magnets 101 and 102 through wires 152a to 152c.

FIGS. 1C and 1D illustrate one example of an exemplary embodiment of a fixing mechanism (electro-permanent magnet) 102. At first, the electro-permanent magnet according to the present invention will now be described. The electro-permanent magnet described in the present specification means a magnet having essential characteristics of being capable of realizing a magnetically attracting state and a non-attracting state by controlling a state in which a magnetic field of a permanent magnet leaks to the outside of the electro-permanent magnet and a state in which a magnetic field of the permanent magnet does not leak to the outside of the electro-permanent magnet with an electrical control from the outside. Accordingly, the structure is not limited to a structure described below, but includes an electro-permanent magnet described in the present specification as long as the structure can essentially exert the above described function.

The operation of the electro-permanent magnet according to the present invention will now be described with reference to FIGS. 1C and 1D. Here, reference numeral 102a denotes magnetic material, reference numeral 102b denotes a polarization fixed magnet, reference numeral 102c denotes a polarization variable magnet, reference numeral 102d denotes a coil and reference numeral 102f denotes a space for housing not-shown wires therein for applying an electric current to the coil 102d. Reference character L denotes magnetic lines of force emitted from the polarization fixed magnet 102b. Reference characters N and S in the figure denote magnetic poles. At first, referring to FIG. 1C, a state in which the mask 200 of magnetic material is magnetically attracted will now be described. Firstly, an electric current is passed through the coil 102d for approximately 0.5 seconds. Thereby, the polarity of the polarization variable magnet 102c is reversed, and the polarities of the polarization fixed magnet 102b and the polarization variable magnet 102c become the same. Thereby, the magnetic field largely leaks to the outside of the electro-permanent magnet, and the magnetic material magnetically attracts the mask 200. Next, a non-attracting (demagnetized) state will now be described with reference to FIG. 1D. Firstly, an electric current is passed through the coil 102d for approximately 0.5 seconds. Thereby, the polarity of the polarization variable magnet 102c is reversed, and the polarization fixed magnet 102b and the polarization variable magnet 102c are converted to a state of attracting each other, in other words, to a state in which the magnetic lines of force do not leak from the surface of the electro-permanent magnet 102. Then, the magnetic material forms a state of non-attracting the mask 200. In this way, the electro-permanent magnet according to the present invention realizes a magnetically attracting state and a non-attracting state as the essence of its characteristics, by making a state in which the magnetic field of the electro-permanent magnet leaks out to the outside and a state in which the magnetic field of the electro-permanent magnet does not leak to the outside, with the use of an electric current applied from the outside.

The polarization fixed magnet 102b needs to be a magnet having a high magnetic flux density in order to achieve a role of generating an attraction force in the electro-permanent magnet 102, and a rare earth magnet is generally used. As the polarization variable magnet 102c, such a magnet, for instance, an aluminum-nickel-cobalt-based magnet is used as to achieve a role of controlling a magnetic flux of the polarization fixed magnet 102b, and have properties of reversing a direction of the magnetic flux (reversing magnetic pole) by receiving a magnetic control from the outside with the use of the coil 101d provided in the outside the polarization variable magnet 102c. The magnet-fixing component 102e is used for fixing accommodated magnets.

When the electro-permanent magnet is used in this way, the magnetic attraction force can be adjusted only by an electrical control with the use of a circuit, when viewed from the point of operation control for the apparatus. Accordingly, the structure of the apparatus is greatly simplified in comparison with the apparatus which is structured only from the permanent magnet, and the apparatus can enhance its reliability and can reduce the price.

FIG. 1E illustrates another example of an exemplary embodiment of a fixing mechanism (electro-permanent magnet). This exemplary embodiment has a structure in which the outer surface of the electro-permanent magnet 102 shown in FIGS. 1C and 1D is covered with non-magnetic material 102g.

The reason of being structured in this way is as follows. For instance, when a film is formed with the use of a mask, a pressure of generally 0.1 Pa to 1.0×10⁻⁶ Pa or occasionally a lower pressure than the before-mentioned pressure is needed during film formation in order to maintain the quality of the film. When material having a large degassing rate is used in such a vacuum, an exhaust system becomes huge, contaminants are formed, and dust is produced, which lead to a large increase of the apparatus cost, so that the degassing rate needs to be decreased to as small a value as possible. In order that an electro-permanent magnet is used under an environment of a high vacuum in which the mask is used for the processing, the component, particularly, the portion exposed to the vacuum needs to decrease its degassing rate to a smaller value than a predetermined value. It is known that the degassing rate can be decreased by employing a buff-polished mild steel, and it is preferable to set a value of released gas achieved by the above described processing, in other words, the degassing rate per unit area at 4.0×10⁻⁴ Pam/s or less (Non-Patent Document 1: “vacuum handbook” edited by ULVAC, Inc., p. 47).

Non-Patent Document 1: “Vacuum handbook” edited by ULVAC, Inc., p. 47

It is considered as one method of realizing such a degassing rate to employ a magnetic stainless steel for a component of the electro-permanent magnet. For instance, a method of employing SUS430 as magnet material is considered.

In the exemplary embodiment of FIG. 1E, the degassing rate is decreased by covering the electro-permanent magnet with non-magnetic material 102g of which the surface has been treated. Specifically, it is considered to subject the surface of the non-magnetic material 102g to surface treatment such as plating treatment of nonelectrolytic nickel plating or the like, blast treatment and polishing treatment, and to degassing treatment (vacuum baking). Alternatively, the surface of the electro-permanent magnet may be subjected to surface treatment such as resin coating or ceramics coating of applying resin or ceramic material capable of coping with a vacuum thereto, plating treatment, blast treatment, polishing treatment and vacuum baking treatment. Furthermore, the electro-permanent magnet can also be covered with a metal plate, a resin plate or a ceramic plate which has been subjected to vacuum baking treatment, plating treatment, blast treatment, polishing treatment, resin coating or ceramic coating.

Furthermore, the surface of the electro-permanent magnet may also be covered with non-magnetic material which is generally used in a vacuum member, for instance, stainless steel (SUS304) or an aluminum alloy. The plate thickness to be adopted at this time is preferably 0.1 to 3 mm in consideration of the workability.

Another method of reducing the gas to be released includes a method of: arranging a non-magnetic metal member which has been subjected to surface treatment described in the paragraph 0054 stage on a magnet-fixing member 102e, and fixing the non-magnetic metal member to magnetic material 102a with welding, which is produced from SS 400 (rolled member for structure for general) or the like, which has been subjected to the surface treatment described in the paragraph 0054 stage.

In addition, though wires are housed in 102f in order to supply an electric current to a coil 102d in the electro-permanent magnet, a method of introducing the wires into 102f in the inner part of the electro-permanent magnet 102 in a vacuum state from the outside in an atmospheric state may employ a commercial current-introduction terminal for vacuum (field through).

The contact plane of the electro-permanent magnet with respect to an article to be attracted needs to be worked as a result of responding to a functional requirement aiming at enhancing the productivity of the apparatus. In the exemplary embodiment illustrated in FIG. 1E, the working accuracy for the contact plane can be secured without changing a process of manufacturing the electro-permanent magnet 102. As for points to keep in mind, the non-magnetic material 102g needs to be non-magnetic material so as not to give an influence to the magnetic flux, and because the magnetic attraction force decreases depending on the distance of the contact plane, a preferable condition relating to the non-magnetic material 102g needs to be derived. For instance, it is preferable to employ non-magnetic material capable of being used in the vacuum such as an austenitic stainless steel, an aluminum alloy, a titanium alloy, an elastomer, glass and ceramics, as non-magnetic material, and to set the distance of the contact plane, in other words, the thickness of 102g at approximately 0.001 to 5 mm.

When an object to be processed 300 is processed in a vacuum processing apparatus using a mask attraction mechanism illustrated in FIG. 1A, the electro-permanent magnet 102 contacts the object. The contact plane of the electro-permanent magnet 102 with respect to the object to be processed 300 is provided with irregularities of an embossed shape or a fine pin shape, and the contact area is desirably set at 98% or less of the surface area of the surface of the electro-permanent magnet 102. The first reason is that the contact plane of the electro-permanent magnet 102 is repeatedly brought into contact with the object to be processed 300 and accordingly needs to prevent contaminants such as dirt from depositing thereon by decreasing the contact area as much as possible. The second reason is that it is necessary to improve the detachability of the object to be processed 300 by decreasing the contact area, because the electro-permanent magnet 102 has a feature of having a residual magnetic field though being slight (approximately 30 gausses) in a non-attracting (demagnetized) period, and the residual magnetic field works as detachment resistance when the object to be processed 300 is detached therefrom. It is preferable to set a value of the contact area of the electro-permanent magnet 102 with the object to be processed 300 at 98% or less of the surface area of the surface of the electro-permanent magnet 102.

FIG. 1F illustrates an exemplary embodiment in which a contact plane of the electro-permanent magnet 102 with respect to the object to be film-formed 300 is embossed. An embossing process is a process of arranging cylindrical protrusions on the surface of the electro-permanent magnet 102 in a staggered form. The contact plane has projection parts 102h (contacting portion) on its surface, and there are gap spaces 102i in the vicinity of the projection parts 102h. The contact area can be reduced by subjecting the surface to such surface processing. The contact area can be also changed by changing the processed shape.

It is also possible to provide a mechanism which can introduce and exhaust a gas into and from fine spaces that are formed by the electro-permanent magnet 102 and the object to be processed 300, and a mechanism which controls the gas pressure, for the processing with the use of the vacuum processing apparatus which employs the mask attraction mechanism shown in FIG. 1. It is possible for controlling the temperature of the object to be processed 300 to form a layer having adequate thermal conductivity in a space between the object to be processed 300 and the electro-permanent magnet 102, by providing a mechanism in the apparatus, which can evacuate the space and introduce a gas into the space, and controlling the gas pressure. Such a structure is used in an electrostatic chuck or the like. It is possible to form a layer having adequate thermal conductivity by subjecting the electro-permanent magnet 102 to the process imparting the function, and introducing the gas into the space at a predetermined pressure. A special technique is not necessary for the above described necessary working. The metal surface of the electro-permanent magnet 102 can be easily worked in a similar way to ordinary mechanical working as in the case of forming a through-hole or a groove.

FIG. 1G illustrates an exemplary embodiment of the mask attraction mechanism having the contact plane of the electro-permanent magnet 102 with respect to the object to be film-formed 300 subjected to an embossing process, and a through-hole 102j through which the gas can be introduced into and exhausted from the communication void space 102i. The embossing process forms cylindrical protrusions on the surface of the electro-permanent magnet 102 in a staggered form, and communication void spaces 102i communicate with each other in the contact plane. Accordingly, the gas can spread into the whole communication void space or the filled gas can be exhausted from the whole communication void space, by providing the through-hole in an arbitrary portion. Thereby, the pressure of the gas in the communication void space 102i can be controlled to a desired value. The through-hole 102j is connected to a vacuum pump 163 by an exhaust pipe 161 through a valve 162, and a gas in the communication void space 102i is exhausted by operating the vacuum pump 163 and opening the valve 162. The pressure of the gas can be confirmed through a vacuum gauge 164. In addition, another through-hole 102j introduces the gas which passes through a gas introduction pipe 171 from a gas bomb 173, into the communication void space 102i, when the valve 172 is opened. The pressure of the gas can be confirmed through a pressure gauge 174.

The previous description with reference to FIG. 1E was on the case in which the surface of the electro-permanent magnet 102 is covered with the non-magnetic material 102g that has been subjected to the surface treatment. Now, another exemplary embodiment will be descried with reference to FIG. 1E. In another exemplary embodiment, in processing with the use of the vacuum processing apparatus having the mask attraction mechanism shown in FIG. 1, as is illustrated in FIG. 1E, the mask attraction mechanism was structured so as to insert a thin plate 102g between the electro-permanent magnet 102 and the object to be processed 300, and fix the object to be processed 300 through the thin plate 102g. The electro-permanent magnet 102 is required to have a function as a working plane for holding the object to be processed 300, and accordingly needs to have adequate flatness. However, the electro-permanent magnet 102 is structured by assembling a plurality of components such as a frame, a plurality of magnets and magnetic material, so that there are irregularities thereon. The steps can be eliminated by fixing the object to be processed 300 through the thin plate having sufficient flatness. In order to further enhance the flatness, it is allowed to previously prepare an extra space for working on the plate, and subject the plate to flattening working in a state of making the plate fixed on the electro-permanent magnet 102. In order to fix the electro-permanent magnet 102 to the plate, a technique of using an adhesive, bolting, welding the periphery or the like is preferable. The magnetic attraction force of the electro-permanent magnet 102 depends on a distance between the electro-permanent magnet 102 and the object to be processed 300, in other words, a thickness of the thin plate. Accordingly, the preferable thickness of the thin plate is desirably 100 μm to 3 mm. This thin plate can be further subjected to plating treatment, blast treatment, polishing treatment and vacuum baking.

When a contact plane with respect to the object to be processed is worked for the purpose of enhancing the productivity of the apparatus, in processing with the use of the vacuum processing apparatus having the mask attraction mechanism shown in FIG. 1A, the contact plane of the electro-permanent magnet 102 with respect to the object to be processed 300 is desirably worked so as to acquire the flatness of 50 μm or less. When the film is formed on the object to be processed (to be film-formed) in a state of being fixed, if the contact plane was not reliably flattened, it incurs the degradation of the film-forming accuracy. Usually, the object to be processed 300 (glass substrate, for instance) is formed so as to have adequate flatness (10 μm or less, for instance), so that the contact plane of the electro-permanent magnet 102 also needs to have the same degree of flatness. As for a preferable condition, the flatness is desirably 50 μm or less. A mask having a size of 1,300 mm×800 mm is flexed by 50 μm due to its own weight, and the contacted plane of the electro-permanent magnet with respect to the object to be processed needs to have the same degree of flatness as that of the flexure of the mask due to its own weight.

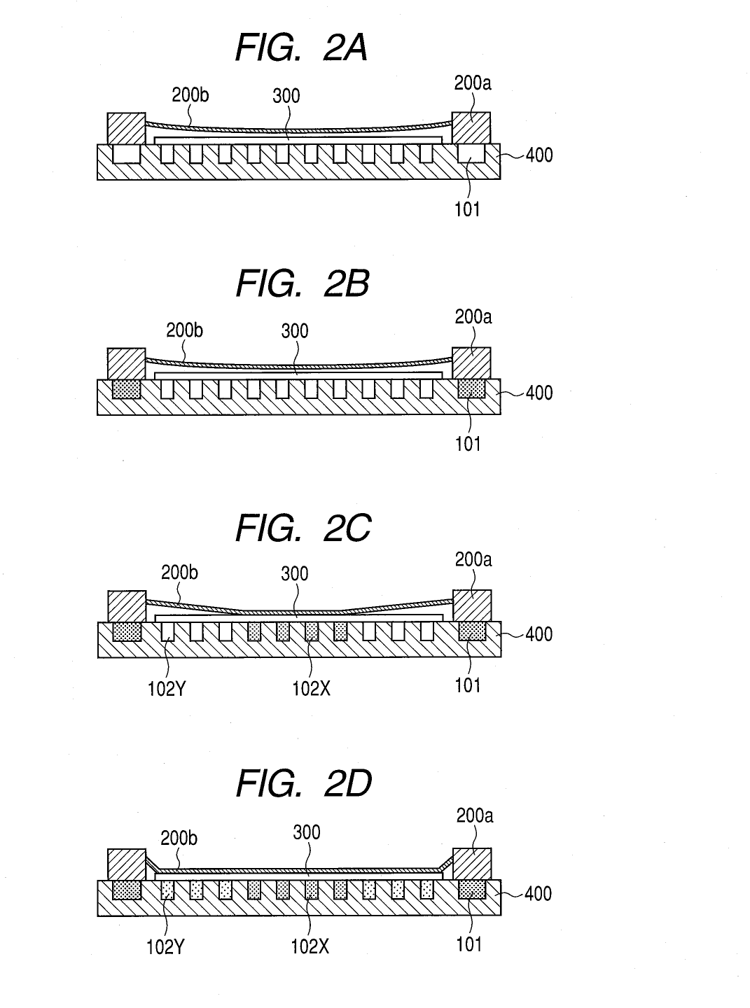

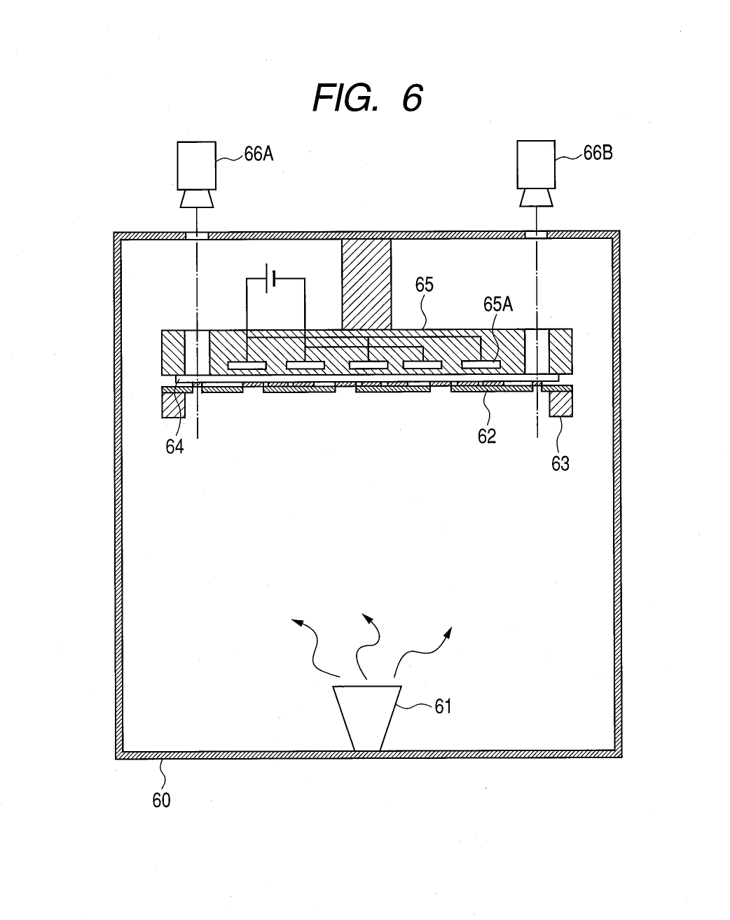

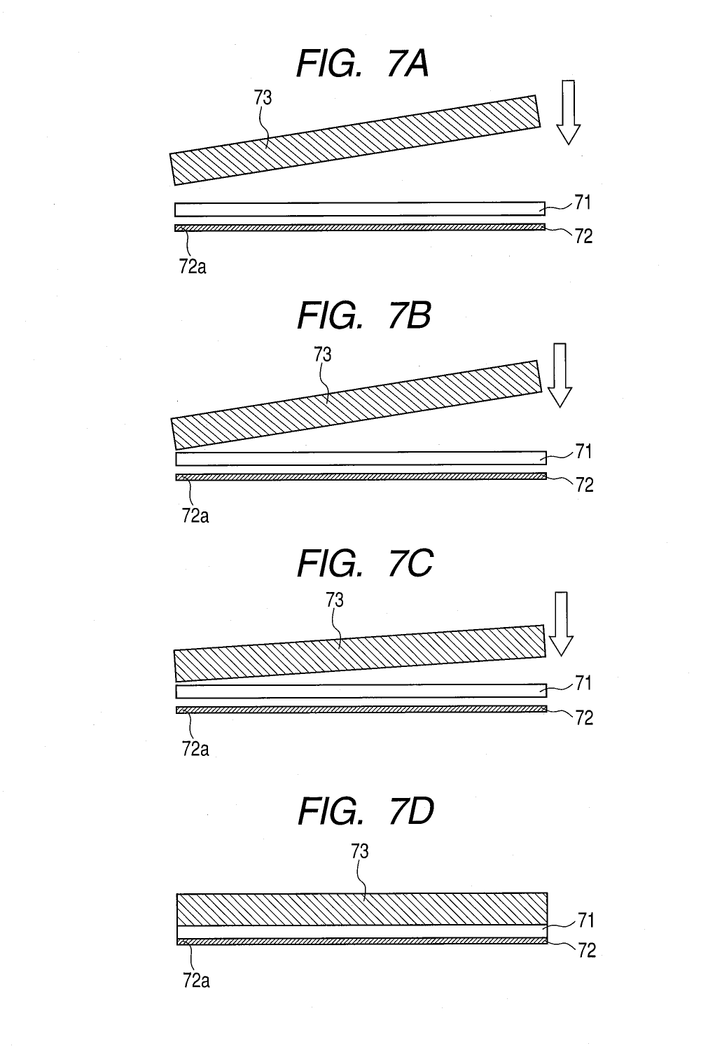

FIG. 2 is a conceptual view illustrating the steps starting from the alignment of the mask 200 with respect to the object to be processed 300 and ending in vapor-deposition preparation, in the vacuum processing apparatus according to the present invention. In fixing mechanisms (electro-permanent magnets) 101, 102X and 102Y, a portion shown by a white color shows a non-attracting state, and in the case of being shown by a black color, the portion shows an attracting state. The state illustrated in FIG. 2A shows a state in which the mask 200 and the object to be processed 300 are aligned. The object to be processed 300 is mounted on a base 400, and the mask 200 (200a and 200b) is positioned thereon. In the vacuum processing apparatus, at first in a state of FIG. 2A, a relative position of the mask 200 to the object to be processed 300 needs to be determined on the plane of the base 400 so as to become a value in a range of predetermined accuracy. When the mask 200 and the object to be processed 300 are aligned, either of them may be moved. For instance, an alignment operation is achieved by previously forming alignment marks on a predetermined position of the object to be processed 300 and on a corresponding position on the mask 200, and aligning the positions while observing the positions through a camera, as in FIG. 6 which illustrates a conventional technology. When the mask 200 and the object to be processed 300 are relatively moved, if both of them contacted each other, a scratch can be formed in the object to be processed 300. Accordingly, as was described in FIG. 2A, a fixed gap is provided between both of them so that both of them do not come in contact with each other to solve the problem. On the other hand, if this gap was large, the gap causes misalignment when the mask membrane plane 200b and the object to be processed 300 are brought into close contact with each other and fixed there in the following procedure, so that the gap is desirably formed as narrow as possible. Specifically, the gap is desirably formed so as to be 500 μm or less.

FIG. 2B illustrates a state in which the mask frame 200a is attracted and fixed with a magnetic force, by independently operating only the fixing mechanism 101 for a mask frame after having finished the alignment. In a structure of a control circuit for controlling an attraction operation and a non-attraction operation of the electro-permanent magnets 101 and 102 illustrated in FIG. 2, a power source which drives the electro-permanent magnet 101 for fixing the mask frame and a power source which drives the electro-permanent magnet 102 for fixing a mask membrane plane are independently operated, respectively. The electro-permanent magnet 101 for fixing the mask frame generates a magnetic attraction force when an electric current is applied from a not-shown driving power source for a short period of time. At this time, only the mask frame 200a is fixed on the base 400, and a space between the mask membrane plane 200b and the object to be processed 300 has a predetermined gap, so that misalignment does not occur by this operation.

FIG. 2C illustrates a state in which the central part of the object to be processed 300 is brought into contact with the central part of the mask membrane plane 200b, by independently operating only the electro-permanent magnet 102X of the central-part fixing mechanism of the mask membrane plane 200b after having fixed the mask frame 200a on the base 400, and elastically deforming the central part of the mask membrane plane 200b by the magnetic force. A mask attraction mechanism according to the present embodiment generates a magnetic attraction force by applying an electric current to the electro-permanent magnet 102X for a short period of time with the use of a not-shown driving power source. The mask attraction mechanism can also secure adequate close contactability by bringing the central part of the mask membrane plane 200b in contact with the object to be processed 300 in a state of having applied the tension to the central part, while causing less wrinkle in the mask 200 and less misalignment than those in the case of making the magnet attract the whole surface at once.

FIG. 2D illustrates a state in which finally both of the mask membrane plane 200b and the plane of the object to be processed 300 thoroughly contact each other, by bringing the center of the object to be processed 300 into contact with the central part of the mask membrane plane 200b, then generating a magnetic attraction force by applying an electric current only to the electro-permanent magnet 102Y of the periphery fixing mechanism of the mask membrane plane 200b for a short period of time, and elastically deforming the peripheral part of the mask membrane plane 200b to a direction of the surface to be processed of the object to be processed 300. The electro-permanent magnets 102X and 102Y for fixing the mask membrane plane 200b are arranged so as to uniformly exert an attraction power on the mask membrane plane 200b. Specifically, the electro-permanent magnets are uniformly arranged in the plane which opposes to the mask membrane plane 200b. The mask attraction mechanism according to the present exemplary embodiment generates a magnetic attraction force by applying a pulse current to the electro-permanent magnet from each not-shown driving power source for approximately 0.5 seconds.

At the time when a series of operations described in FIGS. 2 to D have been finished, the mask membrane plane 200b and the object to be processed 300 are in a state of closely contacting each other due to an attraction power, and the object to be processed 300 is held and fixed by being pushed to the base 400 by the mask membrane plane 200b. Thereby, the object to be processed 300 can be fixed on the base 400, even though being non-magnetic material such as a glass substrate. As for a magnetic attraction force for the purpose, the electro-permanent magnet 101 for fixing the mask frame 200a thereon desirably shows a magnetic attraction force which can hold and fix the whole mask 200 against its gravity. The magnetic attraction force of the electro-permanent magnets 102X and 102Y for fixing the mask membrane plane desirably shows a magnetic attraction force larger than the total weight of the mask membrane plane 200b and the object to be processed 300 contacting the mask.

Adequate close contactability can be reliably obtained by bringing the mask membrane plane 200b in contact sequentially with the center to the periphery of the object to be processed 300, while causing no wrinkle and no misalignment between the mask membrane plane 200b and the object to be processed 300. In comparison with means of attracting a mask sequentially from its one end, which is a conventional technology described in the Patent Document 6, this mask attraction mechanism can easily cope with the case that the size of the mask 200 or the object to be processed 300 have increased. The reason is because the mechanism can bring the mask membrane plane 200b in contact sequentially with the central part toward the periphery of the object centrosymetrically, so that if the wrinkle was formed on the mask membrane plane, the distance by which the mask membrane plane deforms (escapes) is always shortest. On the other hand, if the mask membrane plane was attracted from one end, a distance from which the generated wrinkle is escaped is greatly affected by the size of the object to be processed, because there is the distance only in one direction. Thus, the mechanism can enhance the close contactability without causing misalignment due to an impact and a scratch due to the contact compared to that in the conventional technology, and as a result, can reduce the misalignment between the film pattern and the mask pattern. In addition, the present invention can easily cope with a request of further enlarging the size of the object to be processed.

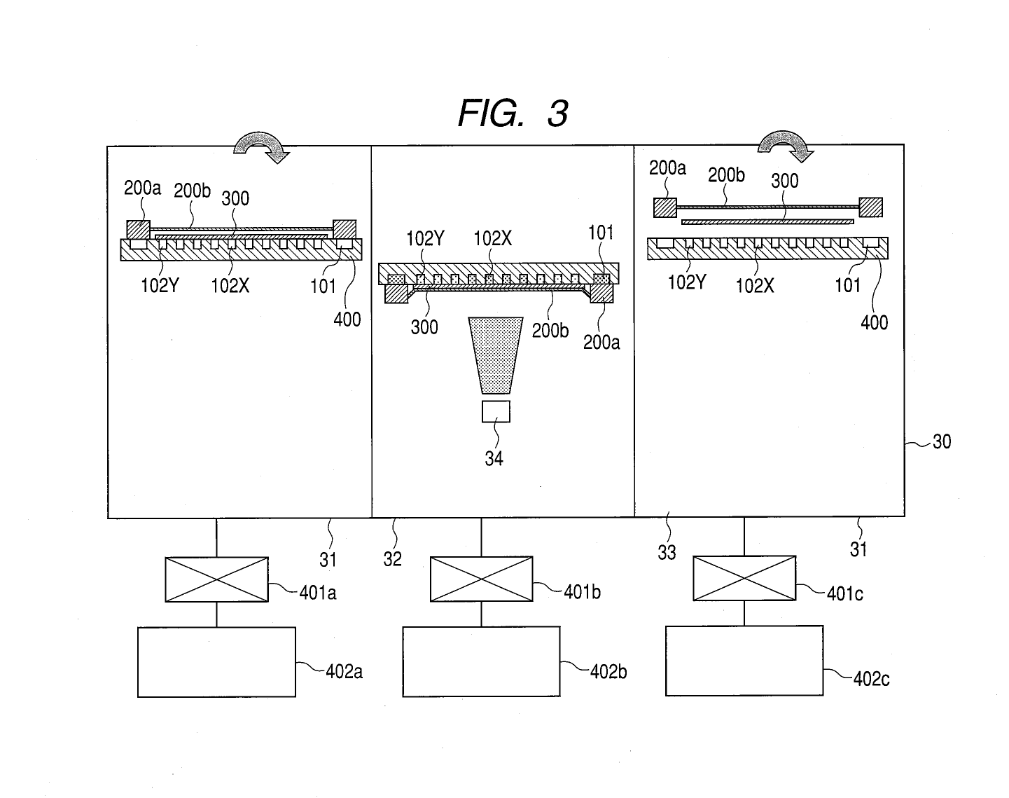

Here, the transportation and collection operations for the object to be processed 300 will be described with reference to FIG. 3. A vacuum processing apparatus 30 illustrated in FIG. 3 is connected to vacuum exhausting means (402a, 402b and 402c) such as a vacuum pump, through valves (401a, 401b and 401c). Steps of loading, aligning and fixing the object to be processed 300 are conducted in a chamber 31 for loading/aligning/fixing the object to be processed, which is illustrated in FIG. 3. The object to be processed 300 such as a substrate is transported to the chamber 31 for loading/aligning/fixing the object to be processed, by a not-shown transportation system. The transported object to be processed 300 is mounted on the electro-permanent magnet 102, by not-shown means for delivering the object to be processed. The mask 200 structured by the mask frame 200a and the mask membrane plane 200b is transported to the base 400 by a not-shown mask transportation system. The object to be processed 300 and the mask 200 which have been transported in this way are aligned in the chamber 31 for loading/aligning/fixing the object to be processed as was described in FIG. 2, and are prepared for vapor deposition. The operation of the electro-permanent magnets 101, 102X and 102Y is the same as that described in FIG. 2. When the preparation for the vapor deposition has been finished, a rotation mechanism in the inner part of the chamber 31 for loading/aligning/fixing the object to be processed is operated, and reverses the object to be processed 300 so as to prepare for the vapor deposition in a vapor-deposition chamber 32. Then, the reversed object to be processed 300 is transported to the vapor-deposition chamber 32 by the transportation system, and a vapor-deposition step is carried out.

The object to be processed 300 is collected after the vapor deposition has been conducted by using a vapor-deposition source 34 in the vapor-deposition chamber 32. Firstly, at this time, the object to be processed 300 after having vapor-deposited thereon is transported to a chamber 33 for releasing the fixation and loading out the object to be processed, by a not-shown transportation system. Next, a rotation mechanism in the inner part of the chamber 33 for loading out the object to be processed is operated, converts the object to be processed 300 into a state of being reversed from that in a vapor-deposition period, and sets the object to be processed 300 over the base 400. The object to be processed 300 which has been reversed from the state in the vapor-deposition period by the rotation mechanism is separated from the base 400 through the operation of releasing a fixing state of the fixing mechanisms 101 and 102 in the chamber 33 for releasing the fixation and discharging the object to be processed. Then, not-shown means for delivering the object to be processed delivers the object to be processed 300 to the transportation system, and the transportation system carries the object to be processed 300 out to a predetermined position thereby to collect the object to be processed 300.

A glass substrate is widely used as a substrate for a flat panel display, and in such an application, a fixing function has been conventionally secured by installing a device such as an electrostatic chuck on the base 400. The mask attraction mechanism according to the present invention can realize the same fixing function as that of the electrostatic chuck without using the electrostatic chuck, and can reduce an apparatus cost. In addition, the procedure described in FIGS. 2A to 2D can be easily programmed, and accordingly can be easily automated by incorporating the above described program into an operation program of the apparatus, which can realize the saving of the power of the apparatus. Incidentally, the present embodiment describes on the vacuum vapor-deposition apparatus, but can be applied to a sputtering method, a chemical vapor-deposition method and the like, and does not depend on a film-forming method.

As was described above, the mask attraction mechanism separates the operation of generating/releasing actions of the mask frame 200a which occupies the most part of the weight of the mask, from the operation of generating/releasing actions of the mask membrane plane 200b which needs close contactability with the object to be processed 300, and thereby can prevent a misalignment of the object to be processed due to an impact which can occur in an aligning operation and a scratch due to the contact. Thereby, the vacuum processing apparatus can conduct processing such as film formation while keeping an accurately aligned state, can conduct the processing such as alignment and film formation without dividing a region into ranges in which alignment accuracy can be secured, as in a conventional technology described in the patent document 4, and can conduct such a mask processing of high accuracy as to be capable of coping even with a large-sized object to be processed.

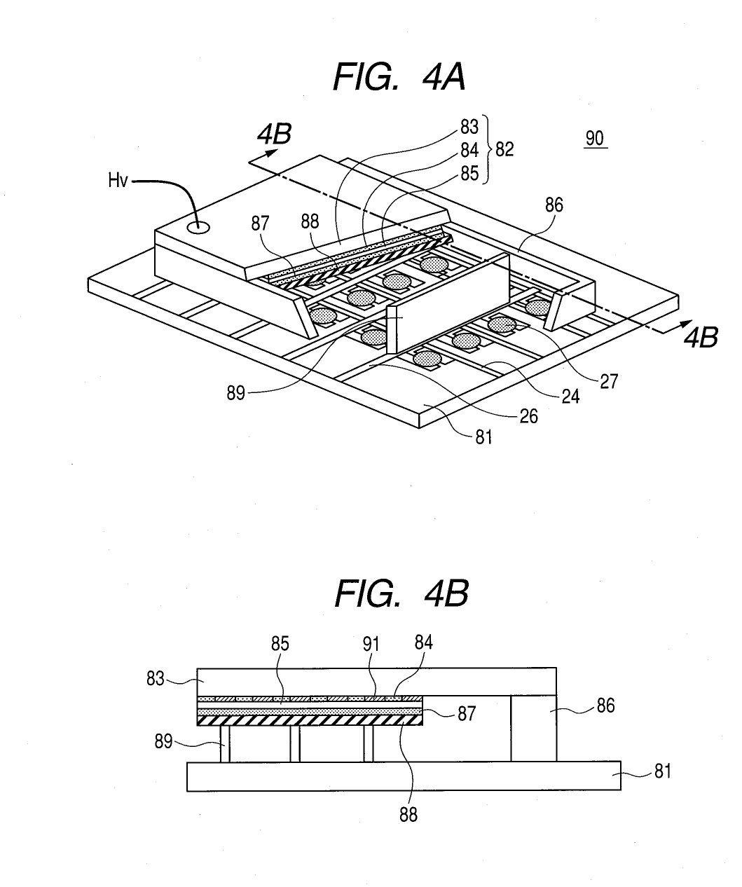

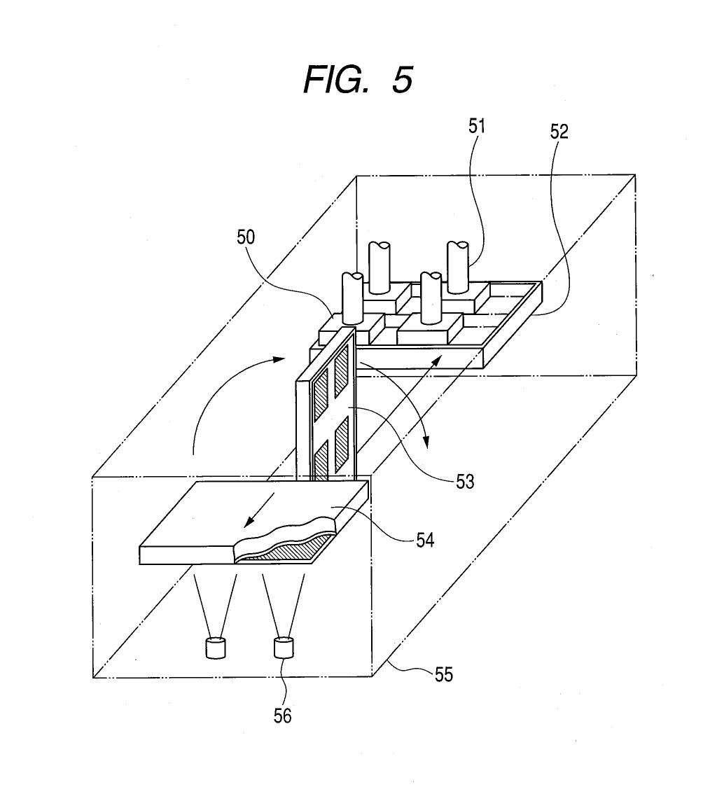

FIGS. 4A and 4B illustrate one example of an image display apparatus manufactured by using a vacuum processing apparatus according to an exemplary embodiment in the present invention. A supporting frame 86 surrounds the periphery of the inner part in a state of making two glass substrates of an electron source substrate 81 and a face plate 82 horizontally oppose to each other at a fixed distance and vertically installing a supporting member which is referred to as a spacer 89. Thereby, an airtight chamber 90 has a structure of being surrounded by the two substrates and the supporting frame 86. The face plate 82 has a structure of having a fluorescent film 84 and a metal back 85 stacked on a glass substrate 83. The electron source substrate 81 has a structure in which electroconductive portions such as wires in a Y-direction 24, wires in an X-direction 26 and an electroconductive film (device film) 27 are stacked thereon.

An image is displayed by applying voltage to the electron sources through wires in the Y-direction 24, wires in the X-direction 26 and the electroconductive film (device film) 27 according to a predetermined procedure, after having formed this airtight chamber 90, and making emitted electrons collide against the fluorescent film 84 on the opposing face plate 82. In order that the airtight chamber 90 works with high reliability, a black conductor 91, a non-vaporizing type getter 87 need to exist in the space of the inside so as to keep the function, and the films need to be previously formed on the face plate 82. Particularly, the non-vaporizing type getter 87 need to be arranged with a predetermined pattern due to restriction on the function. When a film is formed on the pattern portion by using a mask in a vacuum processing apparatus according to the present invention, a high definition image display device with high display quality can be realized. In other words, the image display device using a glass substrate of a large area can be manufactured in high pattern accuracy with high productivity and at a low cost, by using a processing apparatus according to the present invention.

Incidentally, the above described exemplary embodiment was described based on a demagnetizable type of an electro-permanent magnet, in which a magnetic attraction force is switched on and off by an electric current applied for a short period of time. Some of the combination of electromagnet and permanent magnets are normally a permanent magnet, and has the magnetic attraction force off only when an electric current has passed therethrough. In the former case of the electro-permanent magnet, when the magnetic attraction force is switched ON from OFF or OFF from ON, the electric current is passed therethrough for a short period of time. On the other hand, in the latter case, when the magnetic attraction force is desired to be switched OFF from ON, the electric current may be continuously passed therethrough in the desired period.

The above described exemplary embodiments do not limit the scope of the present invention, but can be appropriately changed according to teaching or suggestion in the present exemplary embodiment so as to realize the subject matter of the claims in the present invention.

1. A vacuum processing apparatus comprising:
a chamber, the inner atmosphere of which can be exhausted by vacuum exhausting means;
a base for mounting an object to be processed thereon;
a mask of magnetic material disposed at one surface side of the object; and
a magnet disposed at the other surface side of the object, the magnet being configured to attract the mask to bring the mask into contact with the object on the base,
wherein the mask of the magnetic material comprises a mask membrane plane and a mask frame for fixing the periphery of the mask membrane plane, and
the magnet comprises a first magnet fixing unit for attracting the mask membrane plane to bring the plane into contact with the object, and a second magnet fixing unit operable independently from the first magnet fixing unit, for fixing the mask frame to the base.

2. The vacuum processing apparatus according to claim 1, wherein the component of the magnet has a degassing rate from the material in an amount of 4.0×10⁻⁴ Pam/s or less per unit area.

3. The vacuum processing apparatus according to claim 1, wherein the surface of the component of the magnet has been subjected to plating treatment, blast treatment, polishing treatment, resin coating treatment, ceramic coating treatment or vacuum baking treatment, or is covered with a metal plate, a resin plate or a ceramic plate which have been subjected to any one of the above-mentioned treatments.

4. The vacuum processing apparatus according to claim 1, wherein the contact plane of the magnet with respect to the object to be processed is provided with irregularities of an embossed shape or a fine pin shape, and the contact area with respect to the object to be processed is set at 98% of less.

5. The vacuum processing apparatus according to claim 1, further comprising a mechanism which can introduce a gas into and exhaust the gas from a fine space that is formed by the magnet and the object to be processed, and a mechanism for controlling the pressure of the gas.

6. The vacuum processing apparatus according to claim 1, further comprising a thin plate inserted to a space between the magnet and the object to be processed, and wherein the object to be processed is fixed through the thin plate.

7. The vacuum processing apparatus according to claim 1, wherein the thin plate has been subjected to plating treatment, blast treatment, polishing treatment or vacuum baking treatment.

8. (canceled)

9. The vacuum processing apparatus according to claim 1, wherein the first magnet fixing unit comprises a first magnet in the central part thereof which is operable independently from a second magnet in the peripheral part thereof.

10. The vacuum processing apparatus according to claim 1, wherein the first magnet fixing means for the mask membrane plane exerts a magnetic force on the mask membrane plane of the magnetic material so that a fixing operation of the mask starts from the central part of the object to be processed and ends in the peripheral portion thereof.

11. The vacuum processing apparatus according to claim 1, wherein the first magnet fixing unit and the second magnet fixing unit are electro-permanent magnets.

12. The vacuum processing apparatus according to claim 11, wherein the electro-permanent magnet controls the magnetic force power off only when having passed an electric current therethrough.

13-16. (canceled)

17. A method for manufacturing an electron-emitting device display, characterized by a step of processing an object to be processed with the use of the vacuum processing apparatus according to claim 1.

18. A method for manufacturing an organic EL display, characterized by a step of processing an object to be processed with the use of the vacuum processing apparatus according to claim 1.

19. A method for manufacturing a flat panel image display apparatus including a substrate, comprising:
mounting the substrate on a base in a chamber, the inner atmosphere of which is exhausted by vacuum exhausting means;
disposing a mask of magnetic material at one surface side of the substrate; and
bringing the mask of magnetic material into contact with the substrate surface by attracting the mask with magnet means disposed at the other surface side of the substrate, wherein
the mask of the magnetic material comprises a mask membrane plane and a mask frame for fixing the periphery of the mask membrane plane,
a first magnet fixing unit of the magnet means attracts the mask membrane plane to bring the mask membrane plane into contact with the substrate surface, and
a second magnet fixing unit of the magnet means which operates independently from the first magnet fixing unit fixes the mask frame to the base before performing the contact of the mask membrane plane onto the substrate surface.

20. The method according to claim 19, wherein the first magnet fixing unit comprises a first magnet in the central part thereof is operable independently from a second magnet in the peripheral part thereof.

21. The method according to claim 20, wherein the first magnet fixing unit exerts a magnetic force onto the mask membrane plane that a fixing operation for the mask membrane plane is first applied at the central part and then at the peripheral portion.

22. The method according to claim 19, wherein the first magnet fixing unit and the second magnet fixing unit are electro-permanent magnets.
